(19) United States
(12) Patent Application Publication
(10) Pub. No.: US 2012/0153952 A1
(43) Pub. Date: Jun. 21, 2012

(54) METHOD AND SYSTEM FOR GRADIENT LINEAR CORRECTION

(75) Inventors: Silke Maria Lechner, Munchen (DE); Timothy James Hollis, Oxfordshire (GB); Bruce Courtney Campbell Amm, Clifton Park, NY (US)

(73) Assignee: GENERAL ELECTRIC COMPANY, SCHENECTADY, NY (US)

(21) Appl. No.: 12/970,706

(22) Filed: Dec. 16, 2010

(51) Int. Cl. G01R 33/44

(52) U.S. Cl. 324/314; 324/318

(57) ABSTRACT

Methods, systems and computer program products are described for providing gradient linearity correction in a magnetic resonance image. The method in one example obtains, using a simulation, a time-dependent eddy current induced magnetic gradient field produced by a gradient system in response to a gradient switching pulse. Subsequently, the method determines time-dependent eddy current harmonic response coefficients for at least one higher harmonic frequency based upon the time-dependent eddy current induced magnetic gradient field. The method then corrects the magnetic resonance image based upon the time-dependent eddy current harmonic response coefficients.

### BACKGROUND

The present disclosure relates generally to medical image processing and more particularly to gradient linearity correction in magnetic resonance imaging (MRI).

Gradient coils present in MRI machines are used to vary the strength of the magnetic field over an imaging field of view regardless of orientation of a patient. This alteration of the local magnetic field facilitates in creating different images or “slices” of the patient's body in a desired direction, as different radio frequencies are applied.

In image reconstruction, the magnetic field produced by the gradient coils can be approximated as a series of spherical harmonics which characterize the magnetic field as constant, linear, and higher-ordered components. The non-linearity, that is, the higher order components, in the gradient magnetic field introduces image distortions due to incorrect spatial encoding of the signal.

Currently known techniques to correct for gradient non-linearity image distortions rely on unwarping the gradient magnetic fields. The linearity of the gradient coil can be calculated from the geometry of its conductors. The calculated linear, third and fifth order terms are then used to compensate for the non-linear field behavior and hence, correct the images.

These techniques, however, assume that the non-linearity correction coefficients remain constant over time. In reality, the changing magnetic field from the gradient coil induces eddy currents in any nearby conducting structures. These eddy currents cause linear and higher-order harmonic components that exhibit time varying characteristics.

It is possible to correct for the time varying linear term by applying an additional time-varying current to the gradient but this will not necessarily correct the time-varying higher order terms. One currently known technique measures the time-varying higher order terms produced by the eddy currents. Based on the measurement, the time-varying correction coefficients are determined and applied within the imaging software. However, such a measurement is not possible in certain scenarios, for example, while imaging patients with electrically conductive implants.

Therefore, there is a need for a method and system for correcting image distortions produced by eddy current induced non-linear gradient magnetic field in an MRI system in a more accurate and reliable manner.

### BRIEF DESCRIPTION

The above and other drawbacks/deficiencies may be overcome or alleviated by an embodiment of a method for providing gradient linearity correction in a magnetic resonance image. The method obtains, using a simulation, a time-dependent eddy current induced magnetic gradient field produced by a gradient system in response to a gradient switching pulse. Subsequently, the method determines time-dependent eddy current harmonic response coefficients for at least one higher harmonic frequency based upon the time-dependent eddy current induced magnetic gradient field. The method then corrects the magnetic resonance image based upon the time-dependent eddy current harmonic response coefficients.

### DRAWINGS

These and other features, aspects, and advantages of the present system and techniques will become better understood when the following detailed description is read with reference to the accompanying drawings in which like characters represent like parts throughout the drawings, wherein:

FIG. 1 is a schematic block diagram of a magnetic resonance imaging system for use in conjunction with various embodiments of the present system;

FIG. 2 is a flowchart illustrating an exemplary process of performing gradient linearity correction in a magnetic resonance image, in accordance with various embodiments;

FIG. 3 is a flowchart illustrating an exemplary process of obtaining a time-dependent eddy current induced magnetic gradient field, in accordance with various embodiments;

FIG. 4 is a schematic of an exemplary z-gradient system, in accordance with various embodiments;

FIG. 5 illustrates an exemplary gradient switching pulse applied to the gradient system, in accordance with various embodiments;

FIG. 6 illustrates a field map of a z-component of a reference magnetic gradient field produced by the gradient system, in accordance with various embodiments;

FIG. 7 illustrates time-dependent eddy current response for a linear component, in accordance with various embodiments;

FIG. 8 illustrates time-dependent eddy current response for a third harmonic component, in accordance with various embodiments; and

FIG. 9 illustrates time-dependent eddy current response for a fifth harmonic component, in accordance with various embodiments.

### DETAILED DESCRIPTION

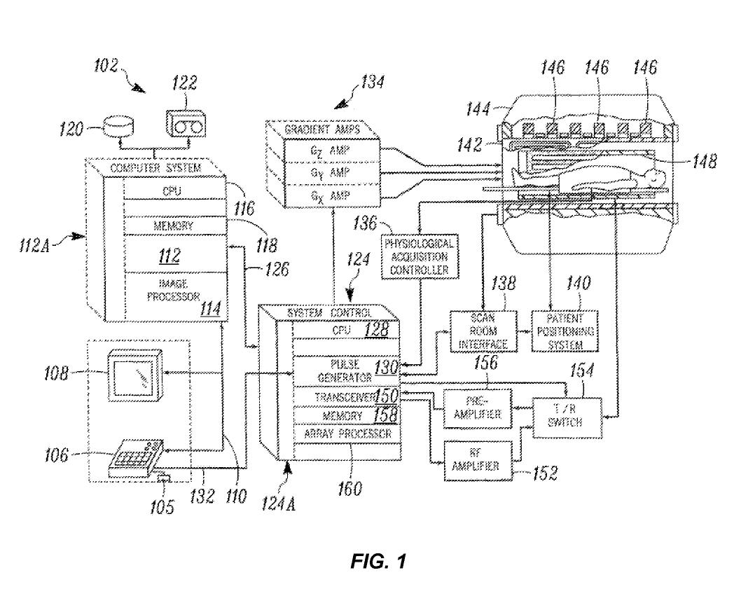

Referring to FIG. 1, the major components of an exemplary magnetic resonance imaging (MRI) system 102 benefiting from incorporating the present system are shown. This is provided for illustrative purposes to explain the elements and flow according to one such system. The operation of the system 102 is typically controlled from an operator console, which includes a keyboard or other input device 105, a control panel 106, and a display screen 108. The operator console communicates through a link 110 with a separate computer system 112 that enables an operator to control the production and display of images on the display screen 108. The computer system 112 includes a number of modules which communicate with each other through a backplane 112A. These include an image processor module 114, a CPU module 116 and a memory module 118, known in the art as a frame buffer for storing image data arrays. The computer system 112 is linked to disc storage 120 and tape drive 122 for storage of image data and programs, and communicates with a separate system control 124 through a high speed serial link 126. The input device 105 can include a mouse, joystick, keyboard, track ball, touch activated screen, light wand, voice control, or any similar or equivalent input device, and may be used for interactive geometry prescription.

The system control 124 includes a set of modules connected together by a backplane 124A. These include a CPU module 128 and a pulse generator module 130 which connects to the operator console through a serial link 132. It is through link 132 that the system control 124 receives commands from the operator to indicate the scan sequence that is to be performed. The pulse generator module 130 operates the system components to carry out the desired scan sequence and produces data which indicates the timing, strength and shape of the RF pulses produced, and the timing and length of the data acquisition window. The pulse generator module 130 connects to a set of gradient amplifiers 134, to indicate the timing and shape of the gradient pulses that are produced during the scan. The pulse generator module 130 can also receive patient data from a physiological acquisition controller 136 that receives signals from a number of different sensors connected to the patient, such as ECG signals from electrodes attached to the patient. And finally, the pulse generator module 130 connects to a scan room interface circuit 138 which receives signals from various sensors associated with the condition of the patient and the magnet system. It is also through the scan room interface circuit 138 that a patient positioning system 140 receives commands to move the patient to the desired position for the scan.

The gradient waveforms produced by the pulse generator module 130 are applied to the gradient amplifier system 134 having Gx, Gy, and Gz amplifiers. Each gradient amplifier excites a corresponding physical gradient coil in a gradient coil assembly generally designated 142 to produce the magnetic field gradients used for spatially encoding acquired signals. The gradient coil assembly 142 forms part of a magnet assembly 144 which includes a polarizing magnet 146 and a whole-body RF coil 148. A transceiver module 150 in the system control 124 produces pulses which are amplified by an RF amplifier 152 and coupled to the RF coil 148 by a transmit/receive switch 154. The resulting signals emitted by the excited nuclei in the patient may be sensed by the same RF coil 148 and coupled through the transmit/receive switch 154 to a preamplifier 156. The amplified MR signals are demodulated, filtered, and digitized in the receiver section of the transceiver 150. The transmit/receive switch 154 is controlled by a signal from the pulse generator module 130 to electrically connect the RF amplifier 152 to the coil 148 during the transmit mode and to connect the preamplifier 156 to the coil 148 during the receive mode. The transmit/receive switch 154 can also enable a separate RF coil (for example, a surface coil) to be used in either the transmit mode or the receive mode.

The MR signals picked up by the RF coil 148 are digitized by the transceiver module 150 and transferred to a memory module 158 in the system control 124. A scan is complete when an array of raw k-space data has been acquired in the memory module 158. This raw k-space data is rearranged into separate k-space data arrays for each image to be reconstructed, and each of these is input to an array processor 160 which operates to Fourier transform the data into an array of image data. This image data is conveyed through the serial link 126 to the computer system 112 where it is stored in memory, such as disc storage 120. In response to commands received from the operator console, this image data may be archived in long term storage, such as on the tape drive 122, or it may be further processed by the image processor 114 and conveyed to the operator console and presented on the display 108 or otherwise communicated to a physician or clinician.

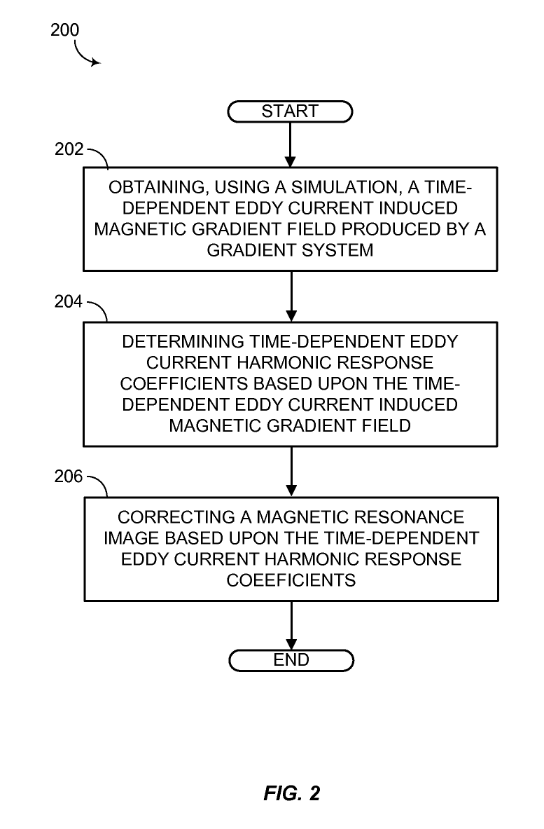

FIG. 2 is a flowchart illustrating an exemplary process 200 of providing gradient linearity correction in a magnetic resonance image, in accordance with various embodiments.

At step 202, a time-dependent eddy current induced magnetic gradient field produced by a gradient system is obtained using simulation. The time-dependent eddy current induced magnetic gradient field includes at least one higher order harmonic component. The time-dependent eddy current induced magnetic gradient field may further include a fundamental frequency component, hereinafter referred to as a linear component. The gradient system includes a gradient coil and one more conducting structures inducing eddy currents. The gradient coil may be a planar gradient coil, a cylindrical gradient coil, an asymmetric gradient coil and the like. According to one embodiment, the one or more conducting structures include cooling tubes. In additional embodiments, the one or more conducting structures may further include a thermal shield, a warm bore and the like.

In one embodiment, a simulation model for the gradient system is developed and used to perform simulations for obtaining the time-dependent eddy current induced magnetic gradient field. The simulation model may be developed based, at least in part, upon one or more design parameters of the gradient system. Example of the design parameters include, but are not limited to, gradient coil geometry, geometry of the one or more conducting structures, types of materials used in the gradient system, and the like. In additional embodiments, conducting structures such as, a thermal shield, a warm bore and the like may also be incorporated in the simulation model.

In one embodiment, the simulation may be carried out using a finite element technique, for example, Maxwell3D by Ansoft. Any other similar simulation software known in the art may also be used. Further, a person skilled in the art will appreciate that the finite element simulation technique is described herein merely as an example, and other simulation techniques may also be suitably used without deviating from the scope and spirit of the invention.

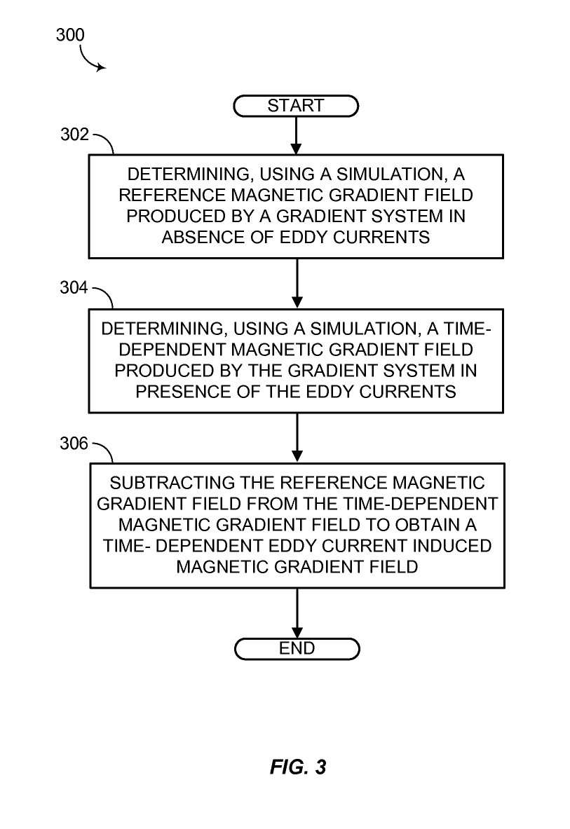

Further, the time-dependent eddy current induced magnetic gradient field is obtained using simulation in response to a gradient switching pulse. In one embodiment, the gradient switching pulse may have trapezoidal shape. In additional embodiments, the gradient switching pulse may have triangular, sinusoidal or any other suitable shape. Various parameters of the gradient switching pulse, for example, pulse width, duty cycle and the like may be appropriately chosen without deviating from the scope and spirit of the invention. Various embodiments for obtaining the time-dependent eddy current induced magnetic gradient field are explained further in conjunction with FIG. 3.

Subsequently, at step 204, the time-dependent eddy current harmonic response coefficients are determined for at least one higher order harmonic frequency based on the time-dependent eddy current induced magnetic gradient field. In one embodiment, the time-dependent eddy current harmonic response coefficients may be determined by performing harmonic decomposition of the time-dependent eddy current induced magnetic gradient field using any harmonic decomposition tools known in the art, for example, MFC 3050 from MetroLab Instruments or Elektra by Vector Fields. A person of ordinary skill in the art will appreciate that the harmonic decomposition technique is merely illustrative and the time-dependent eddy current harmonic response coefficients may also be determined by any other technique known in the art without deviating from the scope of the invention.

In one embodiment, the time-dependent eddy current harmonic response coefficients may be determined at a plurality of time instances during the gradient switching pulse. For example, the harmonic decomposition may be performed on the time-dependent eddy current induced gradient magnetic field, obtained via the simulation, at the plurality of instances, and corresponding time-dependent eddy current harmonic response coefficients may be determined. In one embodiment, the plurality of instances may be uniformly spaced. Alternatively, the plurality of instances may be non-uniform, for example, at a range where the eddy currents occur, the plurality of time instances may be more densely spaced than at a range where no eddy currents are induced.

At step 206, the magnetic resonance image is corrected based upon the determined time-dependent eddy current harmonic response coefficients. In one embodiment, the correction may be performed by importing the time-dependent eddy current induced harmonic response coefficients into image construction software of a magnetic resonance imaging system. An MRI image may be obtained by applying, to the gradient system, any of known imaging pulse or pulse sequence, such as, without limitation, gradient echo pulse, spiral pulse, spin echo pulse, echo planar imaging (EPI) pulse and the like.

In another embodiment, the time-dependent eddy current harmonic response coefficients may be used to determine a compensation factor, a filter, and the like, that can then be used to correct the magnetic resonance image. A person of ordinary skill in the art will appreciate that the correction of the magnetic resonance image may be performed by semi-automated or automated image processing techniques known in the art.

FIG. 3 is a flowchart illustrating an exemplary process 300 of obtaining a time-dependent eddy current induced magnetic gradient field, in accordance with one embodiment. At step 302, a reference magnetic gradient field produced by the gradient system in response to the gradient switching pulse is obtained using the simulation. The reference magnetic gradient field is obtained by performing the simulation without considering eddy currents. The reference magnetic gradient field includes at least one higher harmonic component.

Thereafter, at step 304, a time-dependent magnetic gradient field produced by the gradient system in response to the gradient switching pulse in the presence of eddy currents is obtained using a simulation. This may be performed using, for example, an eddy current solver known in the art. The gradient switching pulse in one example is the same as used in step 302. The time-dependent magnetic gradient field includes at least one higher harmonic component.

Subsequently, at step 306, the time-dependent eddy current induced magnetic gradient field is obtained by subtracting the reference magnetic gradient field, obtained at step 302, from the time-dependent magnetic gradient field obtained at step 304.

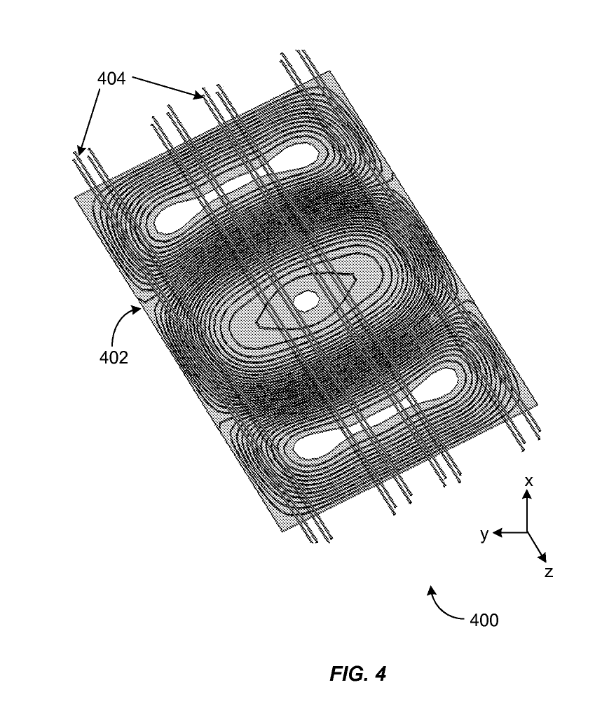

Various steps of the process of providing gradient linear correction are now described for an exemplary experimental set-up. A person skilled in the art will appreciate that the following description is merely illustrative and does not limit the scope of the present system. FIG. 4 is a schematic of an exemplary gradient system 400, in accordance with various embodiments.

The gradient system 400 includes a gradient coil 402 and one or more copper cooling tubes 404. In this example, the gradient coil 402 is a z-gradient coil. In one example implementation, the gradient coil 402 is built of two copper boards connected in series through current leads. In this experimental example, each board has a width of 42 cm, a height of 60 cm, a thickness of 3.2 mm and a cut width of 1.25 mm, according to one embodiment.

In this experimental case, the gradient coil 402 is water cooled using the one or more copper cooling tubes 404. The one or more copper cooling tubes 404 are placed at locations with high heat generation, for example, between each gradient board set and water is pumped through the one or more copper cooling tubes 404 during image acquisition.

In this exemplary case, turns of the gradient coil 402 are represented by single loops. Further, current paths and produced magnetic field strength are simulated for 320 A of current in the exemplary gradient system 400. The maximum current input strength in this case is about 640A. For each axis, symmetry properties were derived by looking at magnetic flux flow at the orthogonal planes. A person of ordinary skill in the art will appreciate that the gradient system 400 merely depicts one experimental setup and various embodiments of the present invention may be used for various other gradient systems. Further, the dimensions and numerical values stated herein are for illustrative purposes only and do not limit the scope of the invention.

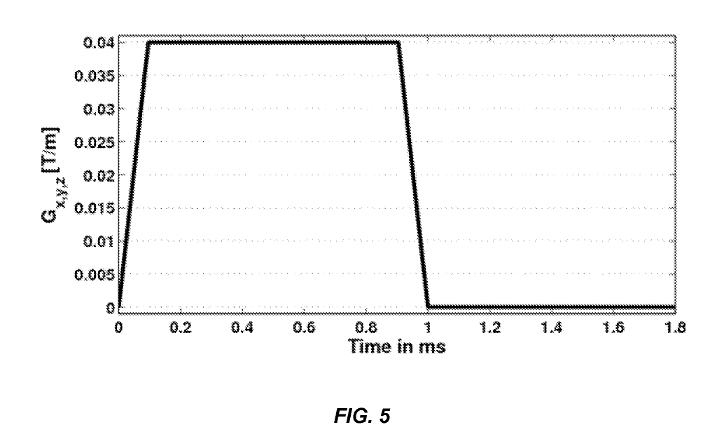

The model thus obtained is simulated using Maxwell3D, or any other such simulation tool, to obtain the time-dependent eddy current induced gradient magnetic field in response to a gradient switching pulse. In the current example, a gradient switching pulse having a trapezoidal shape is applied to the gradient system 400. One example of such a gradient switching pulse is illustrated in FIG. 5. The example gradient switching pulse is 1.8 ms long and is designed to produce a maximum gradient field strength of 0.04 T/m.

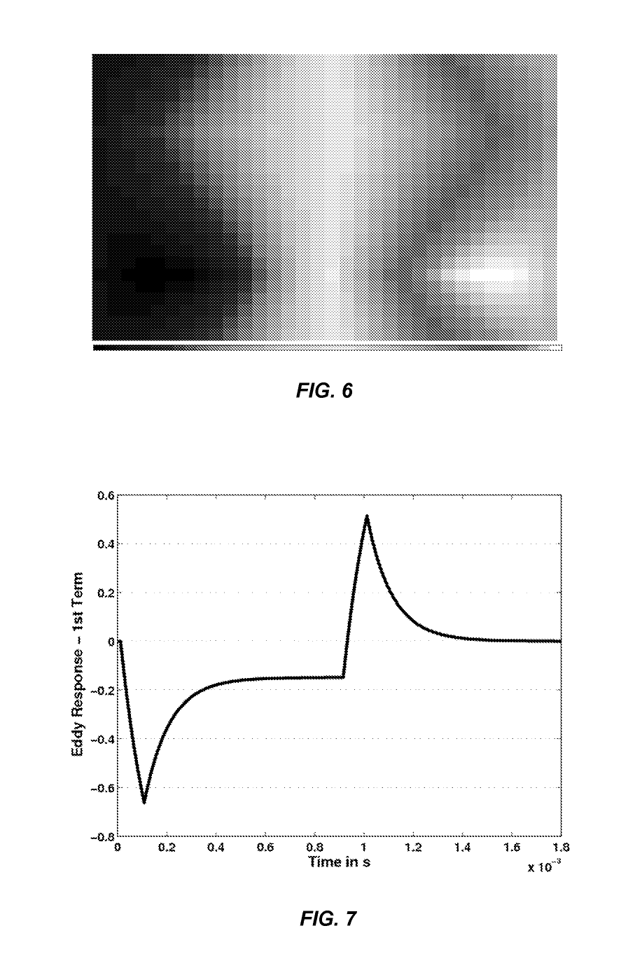

First, a reference simulation is carried out to obtain a reference magnetic gradient field produced by the gradient system 400 in the absence of eddy currents. In this case, gradient component of the reference magnetic gradient field along the z axis is determined. A field map for one such gradient component for z-axis is depicted in FIG. 6. Further, reference harmonic response coefficients at the linear, third harmonic and fifth harmonic frequency are obtained by performing harmonic decomposition of the Bz component of the reference magnetic gradient magnetic field with the help of a harmonic decomposition tool. The Bz component is defined on the surface of a sphere located at the isocenter of imaging field of view.

Thereafter, the time-dependent magnetic gradient field produced by the gradient system 400 in the presence of eddy currents is obtained using an eddy current solver. Further, the time-dependent harmonic response coefficients are determined from the Bz component of the time-dependent magnetic gradient field using the harmonic decomposition tool in a similar manner. These steps are repeated for a plurality of time instances within the duration of the gradient switching pulse. In the example case, the time-dependent harmonic response coefficients are obtained at 451 time instances that are uniformly spaced.

Finally, the time-dependent eddy current harmonic response coefficients are determined by subtracting the reference harmonic response coefficients from the time-dependent harmonic response coefficients.

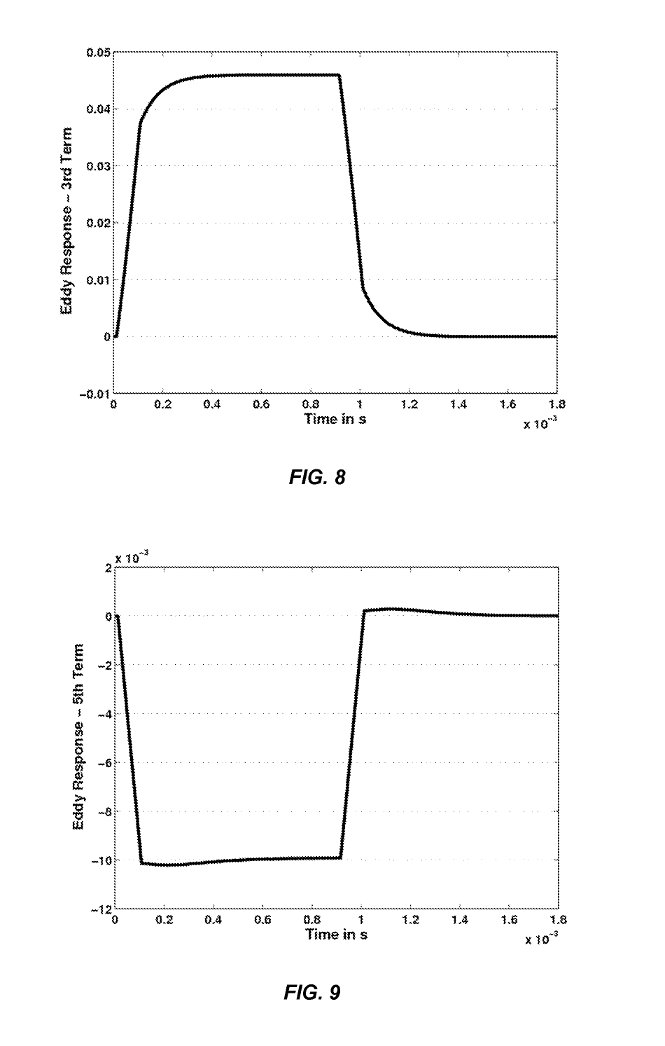

This step is repeated for the linear, the third harmonic and the fifth harmonic components. FIG. 7 depicts a linear component of the time-dependent eddy current response for the z-axis. Similarly, a third harmonic component and a fifth harmonic component of the time dependent eddy current responses are illustrated in FIGS. 8 and 9, respectively, for the experimental set up. The time-dependent eddy current response is used to extract the eddy current harmonic response coefficients that are subsequently used to perform gradient linearity correction in a magnetic resonance image.

The experimental set-up described herein is merely one example and a person skilled in the art will recognize many other suitable variations without deviating from the spirit and scope of the present invention. The manufactured and production embodiments for the gradient coils come in a variety of sizes and shapes along with a number of configurations. However the techniques described herein have equal applicability.

The methods disclosed herein can be embodied in the form of computer or controller implemented processes and apparatuses for practicing these processes. These methods can also be embodied in the form of computer program code containing instructions embodied in tangible media, such as floppy diskettes, CD-ROMs, hard drives, and the like, wherein, when the computer program code is loaded into and executed by a computer or controller, the computer becomes an apparatus for practicing the method. The methods may also be embodied in the form of computer program code or signal, for example, whether stored in a storage medium, loaded into and/or executed by a computer or controller, or transmitted over some transmission medium, such as over electrical wiring or cabling, through fiber optics, or via electromagnetic radiation, wherein, when the computer program code is loaded into and executed by a computer, the computer becomes an apparatus for practicing the method. When implemented on a general-purpose microprocessor, the computer program code segments configure the microprocessor to create specific logic circuits.

While the invention has been described in considerable detail with reference to a few exemplary embodiments only, it will be appreciated that it is not intended to limit the invention to these embodiments only, since various modifications, omissions, additions and substitutions may be made to the disclosed embodiments without materially departing from the scope of the invention. In addition, many modifications may be made to adapt to a particular situation or an installation, without departing from the essential scope of the invention. Thus, it must be understood that the above invention has been described by way of illustration and not limitation. Accordingly, it is intended to cover all modifications, omissions, additions, substitutions or the like, which may be included within the scope and the spirit of the invention as defined by the claims.

1. A method for providing gradient linearity correction in a magnetic resonance image, the method comprising:
obtaining, using a simulation, a time-dependent eddy current induced magnetic gradient field produced by a gradient system in response to a gradient switching pulse;
determining time-dependent eddy current harmonic response coefficients for at least one higher harmonic frequency based upon the time-dependent eddy current induced magnetic gradient field; and
correcting the magnetic resonance image based upon the time-dependent eddy current harmonic response coefficients.

2. The method of claim 1 further comprising building a simulation model for the gradient system, wherein the gradient system comprises at least one gradient coil and one or more conducting structures.

3. The method of claim 1, wherein determining the time-dependent eddy current harmonic response coefficients comprises computing eddy current harmonic response coefficients at a plurality of time instances during the gradient switching pulse.

4. The method of claim 1, wherein determining the time-dependent eddy current harmonic response coefficients comprising performing harmonic decomposition of the time-dependent eddy current induced magnetic gradient field.

5. The method of claim 1, wherein obtaining the time-dependent eddy current induced magnetic gradient field comprises:
determining, using a simulation, a reference magnetic gradient field produced by the gradient system in absence of eddy currents;
determining, using a simulation, a time-dependent magnetic gradient field produced by the gradient system in presence of the eddy currents; and
subtracting the reference magnetic gradient field from the time-dependent magnetic gradient field to obtain the time-dependent eddy current induced magnetic gradient field.

6. A magnetic resonance imaging system comprising:
a gradient system;
one or more processors; and
computer program code stored in a non-transitory computer readable storage medium, coupled to the one or more processors, wherein the computer program code, when executed, is operative to cause the one or more processors to perform magnetic resonance image correction based, at least in part, upon time-dependent eddy current harmonic response coefficients for at least one higher harmonic frequency, wherein the time-dependent eddy current harmonic response coefficients are determined for the gradient system based upon simulation.

7. The magnetic resonance imaging system of claim 6, the gradient system comprises at least one gradient coil and one or more conducting structures.

8. The magnetic resonance imaging system of claim 7, wherein the gradient coil is one of a planar gradient coil, a cylindrical gradient coil, or an asymmetrical gradient coil.

9. A computer program product comprising a non-transitory computer readable medium encoded with computer-executable instructions for providing gradient linearity correction in a magnetic resonance image, the computer-executable instructions, when executed, cause one or more processors to:
perform magnetic resonance image correction based, at least in part, upon time-dependent eddy current harmonic response coefficients for at least one higher harmonic frequency for a gradient system, wherein the time-dependent eddy current harmonic response coefficients are determined for the gradient system based upon simulation.
